(19) United States
(12) Patent Application Publication
(10) Pub. No.: US 2024/0403504 A1
(43) Pub. Date: Dec. 5, 2024

(54) METHOD AND SYSTEM FOR DESIGNING AND CONSTRUCTING NET-ZERO ENERGY BUILDINGS

(71) Applicant: ONX, INC., Carrollton, TX (US)

(72) Inventors: Mohamed Kassim Jahaber, George Town (MY); Alireza Aslani, SW Calgary (CA)

(73) Assignee: ONX, INC., Carrollton, TX (US)

(21) Appl. No.: 18/205,231

(22) Filed: Jun. 2, 2023

(51) Int. Cl. G06F 30/13; G06F 30/18

(52) U.S. Cl. CPC G06F 30/13; G06F 30/18

(57) ABSTRACT

A method of designing and constructing a net-zero energy building (NZEB) includes generating a design model for the NZEB based on a requirement of a user. The design model is for estimating energy consumption for the NZEB over a predetermined period of time. Further, the NZEB includes one or more building elements and one or more air-ventilation elements, and at least one of the one or more building elements includes pre-cast concrete. The method further includes selecting a characteristic for a building parameter of the one or more building elements such that the estimated energy consumption for the NZEB is within a predetermined range. The one or more air-ventilation elements include at least one heat pump with a programmable thermostat for heating, ventilation, and air conditioning (HVAC), and the one or more building elements include one or more photovoltaic (PV) tiles, and one or more organic PV (OPV) windows.

### FIELD OF THE INVENTION

The present disclosure generally relates to construction technology. In particular, the present disclosure relates to design and construction of net-zero energy buildings (NZEBs).

### BACKGROUND OF THE INVENTION

Existing construction technologies involve one-off (e.g., customized) build-on site approaches in which construction material is brought to the construction site where the actual construction is performed. This has been the traditional methodology and approach for many years but has certain inherent challenges, including non-availability of skilled workforce (e.g., manual labor), heavy and expensive on-site machinery, incorrect estimate of completion time of construction projects, delays in delivery of projects, inclement weather, poor quality and wastage of materials, noise and air pollution, and cost involved in disposal of debris. This approach is also “one-off” as it provides no repeatability or scalability leverage. Each building is constructed, and each project is performed differently, and results vary widely, which may be undesirable considering present day demand for symmetrical construction projects with enhanced look and feel. Moreover, constructing each individual component of a building on site incurs significant expenditures in time and resources. It also increases a project's vulnerability to unforeseen factors, such as poor weather, worksite accidents, improper pour, etc.

In order to address the aforesaid shortfalls of these build-on site approaches, some construction projects use pre-cast (prefabricated) building modules. For example, walls, windows, and tiles could be pre-cast at factories under factory scaling, repeatability, and in-factory conditions, and then delivered to a building site for expeditious on-site assembly. These walls, windows, and tiles are lightweight due to less material requirements. Further, the pre-cast walls, windows, and tiles are faster to make and have better performance because of the factory scaling, repeatability, and in-factory conditions.

Further, minimizing energy consumption of buildings (homes) through conventional methodologies (e.g., one-off or customized build-on site approaches) has always been a challenge. Various factors related to one or more elements of a building need to be considered when trying to minimize the energy consumption of the building. Using conventional methodologies to achieve zero or near zero energy consumption requires significant changes in a structure of a building and additional installations that can impact on one or more building elements (e.g., the structure of the building). Such significant changes may include improving one or more properties of the elements of the building such as improving the elements' thermal resistance and air tightness. However, improving the elements' thermal resistance and air tightness is difficult to achieve through conventional solutions. Further, trying to minimize energy waste and improve airtightness of a building after construction (through conventional means) is a difficult task which requires additional time, cost, and quality control that normally is not done by the developer(s) of the building. The quality control is limited during the construction process of a building (using conventional solutions), which makes it difficult to achieve zero energy targets for a building because of extra costs and timing. Also, achieving a truly zero energy consumption in a building (constructed using conventional solutions) could be difficult as the elements that are used (in the construction process) could be inefficient when they are integrated with each other (to form a building). Further, since pre-cast building systems are a new concept, there exists no conventional mechanisms (at present) to minimize the energy consumption of pre-cast buildings.

Accordingly, there remains a need in the art for designing and constructing buildings made up of one or more pre-cast elements (walls, windows, tiles, etc.) and which minimize energy consumption while increasing the on-site energy supply at the pre-cast buildings.

### SUMMARY OF THE INVENTION

Embodiments for designing and constructing NZEBs that address at least some of the above challenges and issues are disclosed.

In a first aspect, the present disclosure is directed to a method of designing and constructing an NZEB. The method includes generating a design model for the NZEB based at least in part on one or more requirements of a user, the design model is for estimating energy consumption for the NZEB over a predetermined period of time, the NZEB including one or more building elements and one or more air-ventilation elements, and at least one of the one or more building elements includes pre-cast concrete. The method further includes selecting at least one characteristic for one or more building parameters of the one or more building elements such that the estimated energy consumption for the NZEB is within a predetermined range. The one or more air-ventilation elements include at least one heat pump with a programmable thermostat for heating, ventilation, and air conditioning (HVAC), and the one or more building elements include one or more photovoltaic (PV) tiles and one or more organic PV (OPV) windows.

In some embodiments, the method further includes, in the design model, varying airtightness and indoor environment quality of the NZEB. Further, varying the airtightness and the indoor environment quality of the NZEB includes sealing the one or more OPV windows, penetrations, and openings in the one or more building elements of the NZEB, and controlling a ventilation airflow design rate and run-time, and an infiltration rate in the NZEB.

Further, in some embodiments, the one or more building elements include walls including a plurality of materials, and the method further includes arranging, in the design model, the plurality of materials in layers to improve an insulation of the walls.

Furthermore, in some embodiments, the insulation of the walls is modeled in a range of R-13 to R-20.

Additionally, in some embodiments, energy is conserved by the NZEB through the modeled insulation of the walls along with one or more materials used in the NZEB including hemp wool.

In addition, in some embodiments, the one or more building elements include slab floors including a plurality of materials, and the method further includes arranging, in the design model, the plurality of materials in layers to improve an insulation of the slab floors.

Additionally, in some embodiments, the insulation of the slab floors is modeled in a range of R-13 and R-17, and the slab floors are fitted based on a designed climate condition to be maintained in the NZEB.

In addition, in some embodiments, the one or more building elements include a ceiling including a plurality of materials, and the method further includes arranging, in the design model, the plurality of materials in layers to improve an insulation of the ceiling.

Additionally, in some embodiments, the insulation of the ceiling is modeled at approximately R-30.

In addition, in some embodiments, the one or more OPV windows are modeled to a U-value of 0.65 or less, and a solar heat gain co-efficient (SHGC) value of 0.26 or less.

In some additional embodiments, the one or more building elements include doors, where the U-value of the doors is modeled to: opaque: 0.21≤½ lite: 0.26>½ lite: 0.30, and where the SHGC value of the doors is modeled to: opaque: no rating≤½ lite: 0.30>½ lite: 0.30.

Additionally, in some embodiments, the method further includes modeling the programmable thermostat based at least in part on the one or more requirements of the user.

In some additional embodiments, the one or more building elements include ducts and air handlers in a conditioned space of the NZEB.

In addition, in some embodiments, the method further includes modeling the at least one heat pump to include a runtime, positive pressure, filtered fresh air ventilation system used for the HVAC.

In addition, in some embodiments, the method further includes using the one or more building elements and the one or more air-ventilation elements to build the NZEB. Further, using the one or more building elements and the one or more air-ventilation elements to build the NZEB includes constructing the NZEB based at least in part on the user requirements and the selected at least one characteristic for the one or more building parameters. In addition, in some embodiments, the estimated energy consumption is zero or less. Additionally, in some embodiments, the one or more building parameters are based at least in part on one or more of a location of the NZEB in a geographic area and an orientation of the NZEB in the geographic area. In some embodiments, the location includes a longitude and a latitude. Further, in some embodiments, the orientation is with respect to a cardinal compass point.

In a second aspect, the present disclosure is directed to a system for designing and constructing an NZEB. The system includes a design module for generating a design model for the NZEB based at least in part on one or more requirements of a user, the design model is for estimating energy consumption for the NZEB over a predetermined period of time. Further, the NZEB includes one or more building elements and one or more air-ventilation elements, and at least one of the one or more building elements includes pre-cast concrete. The system further includes a selection module for selecting at least one characteristic for the one or more building parameters of the one or more building elements such that the estimated energy consumption for the NZEB is within a predetermined range. The one or more air-ventilation elements include at least one heat pump with a programmable thermostat for HVAC, and the one or more building elements include one or more PV tiles and one or more OPV windows.

In a third aspect, the present disclosure is directed to a system for designing and constructing an NZEB. The system includes a processor, and a memory including computer-executable instructions that when executed by the processor perform the steps that include generating a design model for the NZEB based at least in part on one or more requirements of a user, the design model is for estimating energy consumption for the NZEB over a predetermined period of time, the NZEB including one or more building elements and one or more air-ventilation elements, and at least one of the one or more building elements includes pre-cast concrete. The steps further include selecting at least one characteristic for the one or more building parameters of the one or more building elements such that the estimated energy consumption for the NZEB is within a predetermined range. The one or more air-ventilation elements include at least one heat pump with a programmable thermostat for HVAC, and the one or more building elements include one or more PV tiles and one or more OPV windows.

### BRIEF DESCRIPTION OF THE DRAWINGS

Further advantages of the disclosure will become apparent by reference to the detailed description of preferred embodiments when considered in conjunction with the drawings. In the drawings, identical numbers refer to the same or a similar element.

FIG. 1 illustrates the various modules of a system used for designing and constructing an NZEB, according to some embodiments.

FIG. 2 illustrates an exemplary flowchart depicting the various steps involved in designing and constructing an NZEB, according to some embodiments.

FIG. 3 illustrates a sectional view of a building with an integrated PV design including PV tiles on the roof for an NZEB, and further illustrates an enlarged section of an example tile on which one or more PV elements may be placed for an NZEB, according to some embodiments.

FIG. 4 illustrates an example OPV window for the NZEB, according to some embodiments.

FIG. 5 illustrates the various layers including their associated materials of an example wall for an NZEB, according to some embodiments.

FIG. 6 illustrates the various layers including their associated materials of an example slab floor for an NZEB, according to some embodiments.

FIG. 7 illustrates the various layers including their associated materials of an example roof for an NZEB, according to some embodiments.

### DETAILED DESCRIPTION

The following detailed description is presented to enable any person skilled in the art to make and use the disclosure. For purposes of explanation, specific details are set forth to provide a thorough understanding of the present disclosure. However, it will be apparent to one skilled in the art that these specific details are not required to practice the disclosure. Descriptions of specific applications are provided only as representative examples. Various modifications to the one or more embodiments will be readily apparent to one skilled in the art, and the general principles defined herein may be applied to other embodiments and applications without departing from the scope of the disclosure. The present disclosure is not intended to be limited to the embodiments shown, but is to be accorded the widest possible scope consistent with the principles and features disclosed herein.

With modernization in construction-related technologies, there has been a rapid shift from normal customized build on-site construction methodologies to construction using modules or blocks (or artefacts) that can be built off-site and then brought onsite and integrated to form a building structure. However, in such an approach, it may be of utmost concern that the modules (e.g., walls, windows, and tiles) are integrated within the structure in such a manner that the integration minimizes energy consumption while increasing the on-site energy supply (energy supply through sources such as, but not limited to, PV cells, OPV cells, and micro combined heat and power supply) from the buildings. Current manufacturing technologies fail to address this concern. The embodiments of the present disclosure address this concern by providing pre-cast multi-storey (e.g., two-storey) homes (buildings) that use integrated PV design at least with the roof (PV tiles) and the walls (OPV windows). In such embodiments, PV tiles are installed at least on the roof of the building structures, and OPV windows are installed at least on the walls of the building structures.

The disclosed solutions/architectures provide homes having an energy-efficient thermal shell and appliances. When combined with renewable energy systems, over a year the total energy production (from a home) minus the total energy use (of the home) equals zero or positive, while the thermal comforts of the residents (residing inside the home) are increased. The homes (constructed as per one or more of the disclosed solutions) provide advantages of zero or negative external energy supply (zero utility bills) using at least integrated PV design, income from excess on-site energy production using at least integrated PV design, increased lifetime and quality of the homes using at least pre-cast technology, and lower mass and weight (of the buildings) using at least PV tiles and eliminating shingle roofs. The PV tiles and the OPV windows produce more energy than the amount of energy that is consumed in the home. Further, improving the thermal shell of the buildings, using one or more approaches discussed herein, helps in minimizing the energy consumption of a home while maintaining the indoor air quality of the home.

Firstly, the buildings constructed as per one or more of the disclosed solutions reduce the energy consumption of the buildings using (1) highly efficient construction methodologies based on pre-cast technology, and (2) reduced thermal waste from the building's envelope using high energy-efficient building materials. Secondly, the buildings constructed as per one or more of the disclosed solutions supply their associated required energy through integrating PV elements with at least the roof and windows (of the buildings), an arrangement which not only reduces the cost of the construction but also decreases the building's mass.

Through pre-cast technology, insulated pre-cast concrete may be used with minimum energy waste from the buildings. Further, installation of PV tiles on the roof not only helps in supplying the required energy (for the building) but also helps in reducing the roof weight (e.g., structural load) by a significant margin (through elimination of roof shingles and reduction of an amount of rebar used in the construction of the building). In addition, installing PV tiles is easy and has an associated low installation cost. Further, the required energy is supplied through high-performance OPV windows as well. In addition, the OPV windows and doors of the building are well sealed in order to increase the thermal comfort of the residents inside the buildings. Further, the disclosed solutions/architectures provide increased efficiency of PV shingle tiles using innovative cooling design systems under the shingle tiles. Also, it is possible to design both roofs (on which PV tiles are installed), and OPV windows and doors that are aesthetically pleasing, thereby providing a more natural look to the roofs, windows, and doors.

Thus, the disclosed solutions/architectures provide design and construction of pre-cast multi-storey (e.g., two-storey) homes that aim to minimize energy consumption while increasing the on-site energy supply using integrated PV design with the roof (PV tiles) and the walls (OPV windows).

Certain terms and phrases have been used throughout the disclosure and will have the following meanings in the context of the ongoing disclosure.

“R-value” refers to a measure of thermal resistance, where R stands for resistance to heat flow. An R-value is specified for every layer of material, and United States energy codes only refer to the R-values of insulation layers in the prescriptive R-value compliance path.

“Pre-cast concrete” refers to a construction product produced by casting concrete in a reusable mold or form which is then cured in a controlled environment, transported to the construction site, and maneuvered into a targeted place; examples include pre-cast beams, and wall panels for tilt up construction.

“Organic photovoltaic (OPV) windows” refer to photovoltaic windows that generate electric power from sunlight and simultaneously block the heat-producing portion of the solar spectrum, which may drastically cut energy bills of the homes in which the OPV windows are installed.

“IECC” refers to the International Energy Conservation Code. IECC provides three paths for compliance for a building envelope. The first path specifies the required minimum level of insulation in the wall, i.e., R-value; the second path specifies U-factors for the building envelope components; and the third path, in which an annual energy use analysis is required, is based on the total building energy cost budget for heating, cooling, and service water heating.

“Extruded polystyrene (XPS)” refers to a rigid thermoplastic material manufactured from polystyrene. Polystyrene refers to a synthetic, hydrocarbon polymer derived from two petroleum products, benzene and ethylene.

“Hemp wool” refers to strong and woody fibers derived from a hemp plant.

“Thermal transmittance”, also known as “U-value”, refers to the rate of transfer of heat through a structure (which can be a single material or a composite), divided by the difference in temperature across that structure. The better-insulated a structure is, the lower its U-value.

“Solar Heat Gain Coefficient (SHGC)” refers to a standard used to estimate solar radiation that passes through a glass (e.g., of a window) relative to the amount of solar radiation hitting the glass. Further, factors such as reflection, absorption, and transmittance affect the SHGC value.

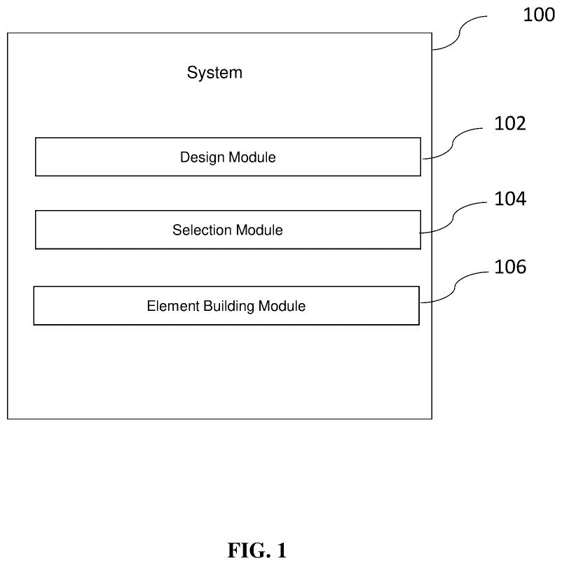

FIG. 1 illustrates the various modules of a system 100 used for designing and constructing an NZEB, according to some embodiments. In the embodiment illustrated in FIG. 1, the system 100 may include modules including a Design Module 102, a Selection Module 104, and an Element Building Module 106. As explained in more detail below, in some embodiments, the one or more modules (102, 104, 106) model building elements (e.g., walls, floors, and ceilings of the NZEB) and air-ventilation elements (e.g., programmable thermostats, heat pumps) of the NZEB to estimate energy consumption of the NZEB for different determined building parameters of the building elements of the NZEB. Then, one or more characteristics of the different determined building parameters may be selected such that the NZEB has an acceptable (predetermined, such as net-zero) energy consumption. A design in accordance with the determined building parameters and their associated selected characteristics may thus be made available before the actual construction of the NZEB begins such that the NZEB has an acceptable (predetermined, such as net-zero) energy consumption. As some non-limiting examples, the one or more characteristics may include window-to-wall ratios, a number of layers of material in a wall, or a shape of a window.

In some embodiments, the Design Module 102 may generate a design model for an NZEB based at least in part on one or more requirements of a user. In some embodiments, the design model may be for estimating energy consumption for the NZEB over a predetermined period of time. In some embodiments, the NZEB may include one or more building elements and one or more air-ventilation elements, and at least one of the one or more building elements may include pre-cast concrete. In some embodiments, the one or more air-ventilation elements may include at least one heat pump with a programmable thermostat for HVAC, and the one or more building elements may include one or more PV tiles and one or more OPV windows. In some embodiments, the Design Module 102 may model the one or more OPV windows to a U-value of 0.65 or less, and a SHGC value of 0.26 or less. In some embodiments, the Design Module 102 may model the programmable thermostat based at least in part on the one or more requirements of the user. In some embodiments, the Design Module 102 may model the at least one heat pump to include a runtime, positive pressure, filtered fresh air ventilation system (which may be external or internal to the system 100) used for the HVAC. In some embodiments, the heat pump may be included in the runtime, positive pressure, filtered fresh air ventilation system. In some embodiments, the Design Module 102 may receive data from the user or any other entity on how to use at least one heat pump with the programmable thermostat. In some embodiments, the one or more requirements of the user may be any requirements (finalized in consultation with an architect) that are associated with the design of the NZEB. In some embodiments, the one or more requirements may include, but are not limited to, aesthetic requirements, material requirements, design requirements, and requirements related to sustainability. Further, the one or more requirements may ensure efficient, durable, comfortable, and resilient homes which may have net zero energy consumption. Further, in some embodiments, the Design Module 102 may be operable to design the one or more building elements and the one or more air-ventilation elements to be used to build the NZEB. Further, in some embodiments, the Design Module 102, by means of the design model, may vary airtightness and indoor environment quality of the NZEB. In some embodiments, the Design Module 102 may model sealing of the one or more OPV windows, penetrations, and openings in the one or more building elements of the NZEB, and may further model controlling of a ventilation airflow design rate and run-time, and an infiltration rate in the NZEB. In some embodiments, the ventilation airflow design rate and run-time may meet the requirements of ASHRAE 62.2-2016. In some embodiments, the infiltration rate may be modeled at 3 ACH50. In some embodiments, the Design Module 102 may determine one or more building parameters of the one or more building elements such that the estimated energy consumption of the NZEB over the predetermined period of time is within a predetermined value or range (e.g., zero or less than zero). In some embodiments, the determination of the one or more building parameters may be based at least in part on data from the user and/or the architect.

In some embodiments, the one or more building elements may include walls including a plurality of materials. In such scenarios, the Design Module 102 may be operable to model arranging the plurality of materials in layers to improve an insulation of the walls. Further, the insulation of the walls may be modeled in a range of R-13 to R-20. Further, energy (associated with the NZEB) may be conserved by the NZEB through the modeled insulation of walls including XPS or hemp wool material. Further, in some embodiments, the one or more building elements may include slab floors including a plurality of materials. In such scenarios, the Design Module 102 may be operable to model arranging the plurality of materials in layers to improve an insulation of the slab floors. Further, the insulation of the slab floors (e.g., over unconditioned space) may be modeled in a range of R-13 to R-17.

Furthermore, in some embodiments, the one or more building elements of the NZEB may include a ceiling including a plurality of materials. In such scenarios, the Design Module 102 may be operable to model arranging the plurality of materials in layers to improve the insulation of the ceiling. Further, the insulation of the ceiling may be modeled at approximately R-30. In some embodiments, the one or more building elements may include doors. In such scenarios, the U-value of the doors may be modeled to: opaque: 0.21≤½ lite: 0.26>½ lite: 0.30, and the SHGC of the doors may be modeled to: opaque: no rating≤½ lite: 0.30>½ lite: 0.30. Further, in some embodiments, the one or more building elements of the NZEB may include ducts and air handlers in a conditioned space of the NZEB. The ducts may be integrated into the buildings in a way such that there is zero duct leakage to the outside. Further, in some embodiments, the insulation levels of the one or more building elements of the NZEB may be modeled to Grade I installation as per ANSI/RESNET/ICC Standard 301. In addition, in some embodiments, the Design Module 102 may be operable to design and model the one or more building elements of the NZEB considering insulated pre-cast concrete based at least in part on data from the user and/or the architect.

In some embodiments, the Selection Module 104 may be operable to select at least one characteristic for one or more building parameters of the one or more building elements such that the estimated energy consumption for the NZEB is within a predetermined range. In some embodiments, the selection of the at least one characteristic may be based at least in part on data from the user and/or the architect. In some embodiments, the at least one characteristic may include characteristics related to massing the NZEB (using pre-cast concrete), characteristics related to a thermal comfort range, characteristics related to the thermal resistance of the envelope of the NZEB and insulation optimization for the NZEB, window-to-wall ratios, glazing (including OPV) characteristics of the one or more elements of the NZEB, and shading related to one or more elements of the NZEB.

In some embodiments, the Element Building Module 106 may be operable to use the one or more building elements and the one or more air-ventilation elements to build the NZEB. In some embodiments, using the one or more building elements and the one or more air-ventilation elements to build the NZEB may include constructing the NZEB based at least in part on the user requirements and the selected at least one characteristic for the one or more building parameters. In some embodiments, the Element Building Module 106 may be operable to use the one or more PV tiles and the one or more OPV windows when using the one or more building elements for building the NZEB. In some embodiments, the integrated one or more PV tiles may be placed on one or more portions of one or more building elements (e.g., the roof of the NZEB) that are along southern and eastern directions. In some embodiments, the one or more OPV windows may be integrated with one or more portions of one or more elements (e.g., the walls of the NZEB) that face southern and eastern directions. In some embodiments, an OPV window (of the one or more OPV windows) may include two layers of glass with attached transparent OPV. In some embodiments, the one or more OPV windows may be modeled to a U-value of 0.65 or less, and an SHGC value of 0.26 or less. Reducing the U-value further (below 0.65) saves more energy. However, considering engineering feasibility and cost accrued to suppliers, some embodiments of the present disclosure may use OPV windows with a U-value of 0.65 since OPV windows designed with smaller U-values (less than 0.65) are expensive. Thus, in some embodiments, the numbers related to U-value, SHGC, and other parameters associated with one or more building elements and one or more air-ventilation elements of the NZEB may be modeled (i.e., optimized) based on one or more of technical, procurement, cost, and comfort conditions. In some embodiments, the Element Building Module 106 may be operable to seal the OPV windows, penetrations, and openings in the one or more elements of the NZEB while using the one or more building elements to build the NZEB. In some embodiments, the penetrations and openings in the one or more building elements of the NZEB may be sealed to achieve 2.3 air changes at 50 Pa.

In some embodiments, an NZEB built through system 100 may produce more energy (onsite at the NZEB) than energy consumed by the NZEB. Further, the conventional solutions used in building energy efficient homes focus on normal methods of construction or modular buildings. However, the current disclosure is related to pre-cast multi-storey (e.g., two-storey) NZEBs. Further, in the present disclosure, the integration of the PV elements with the roof and the windows (of the buildings) not only results in supplying the required energy for the building but also results in the building mass being reduced by eliminating the roof shingles and thereby reducing the amount of the used rebar and other construction materials used in the construction of the building.

In some embodiments, the one or more modules of the system 100 provide the system 100 with a method to design and construct an NZEB by determining a specific envelope (building) design, improving the thermal performance of the envelope, improving airtightness and indoor environment quality of the envelope, using a heat pump and a programmable thermostat for HVAC of the NZEB, and using PV tiles and OPV windows for electricity supply to appliances and other entities in the envelope. In some embodiments, the present disclosure may firstly determine a desired energy usage of a building. Then, a baseline related to the desired energy usage may be identified. Subsequently, energy conservation measures that may be taken (and that may be dependent on the baseline) may be identified. In the next step, strategies related to the desired energy and energy conservation may be identified and recommended. Then, the recommended strategies may be implemented to the pre-cast building (by means of at least generating a design model for the building, the design model is for estimating energy consumption for the building over a predetermined period of time; and selecting at least one characteristic for one or more building parameters of one or more building elements (of the building) such that an estimated energy consumption for the building is within a predetermined range such that the building has net-zero energy consumption. In some embodiments, next, a building in accordance with these strategies is constructed (by means of at least the Element Building Module 106 as discussed above).

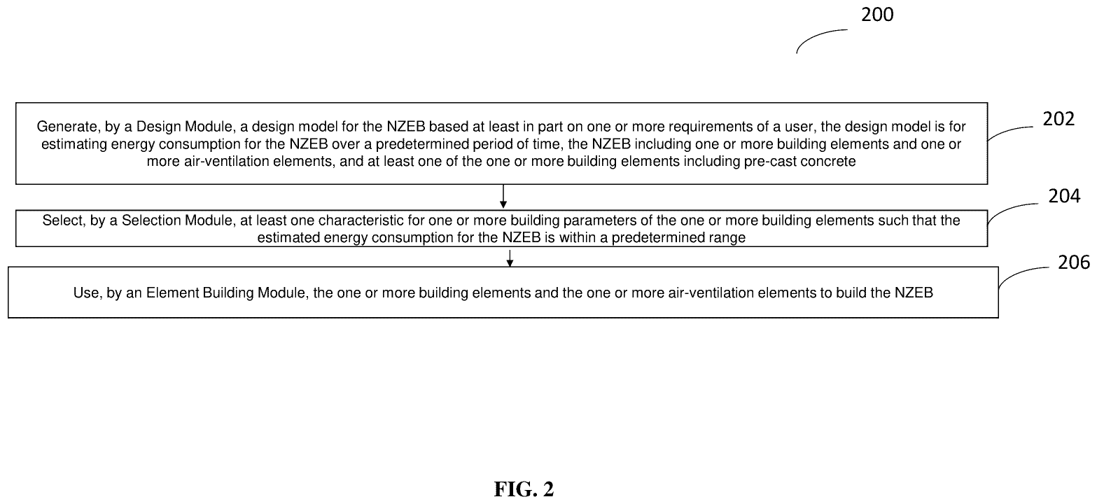

FIG. 2 illustrates an exemplary flowchart 200 depicting the various steps involved in designing and constructing an NZEB, according to some embodiments. FIG. 2 will be explained in conjunction with the description of FIG. 1. In some embodiments, one or more modules of system 100 (described above) may implement one or more steps of method 200.

In some embodiments, in step 202, the Design Module 102 may be operable to generate a design model for the NZEB based at least in part on one or more requirements of a user. The design model is for estimating energy consumption for the NZEB over a predetermined period of time. Further, the NZEB may include one or more building elements and one or more air-ventilation elements, and at least one of the one or more building elements may include pre-cast concrete. In some embodiments, the design model for the NZEB (building) may be generated keeping in mind hot and humid climate conditions (e.g., conditions like those in Miami, Florida), where the cooling load is responsible for the majority of the energy consumption of the building. Therefore, in some embodiments, the generating step may be based at least in part on selection of a site location considering factors that may cast an impact on the thermal comfort of the building (heating/cooling loads). The generating step may further factor in design considerations related to the NZEB. In some embodiments, net-zero energy pre-cast homes must be designed (i.e., the design model may be generated) to satisfy local building codes and the specific requirements of the site that may impact the off-site construction and assembling of the home. In some embodiments, prefabrication may be another important step in the building process of the NZEB. The generating step may also include creating detailed plans and designs for the prefabricated components (to be used in building the NZEB) and coordinating with fabricators to ensure that the components are produced (prefabricated) to exact specifications. Thus, in some embodiments, the generating step includes one or more steps that are important in the building process of the NZEB.

Further, in some embodiments, in step 204, the Selection Module 104 may be operable to select at least one characteristic for one or more building parameters of the one or more building elements of the NZEB such that estimated energy consumption for the NZEB is within a predetermined range. As discussed above, the one or more building parameters may include parameters related to massing the NZEB (using pre-cast concrete), parameters related to a thermal comfort range, parameters related to thermal resistance of the envelope of the NZEB (e.g., roof R-values) and insulation optimization for the NZEB, window-to-wall ratios, glazing (including OPV) characteristics of the one or more building elements of the NZEB, and shading related to one or more building elements of the NZEB.

Furthermore, in some embodiments, in step 206, the Element Building Module 108 may be operable to use the one or more building elements and the one or more air-ventilation elements to build the NZEB. In some embodiments, the Element Building Module 108 may use the one or more PV tiles and the one or more OPV windows when using the one or more building elements to build the NZEB. In some embodiments, one or more building elements (e.g., the roof) of the NZEB may be fully or partially be covered by PV shingle tiles (e.g., on south or west sides) depending at least on the NZEB orientation and the energy supply demand of the NZEB. Further, in some embodiments, using cooling systems (e.g., cooling ducts) under PV shingle tiles may help to increase the efficiency of output from PV tiles. Furthermore, in some embodiments, overhand and shadow for the OPV windows may depend at least on the OPV energy generation and heat gain.

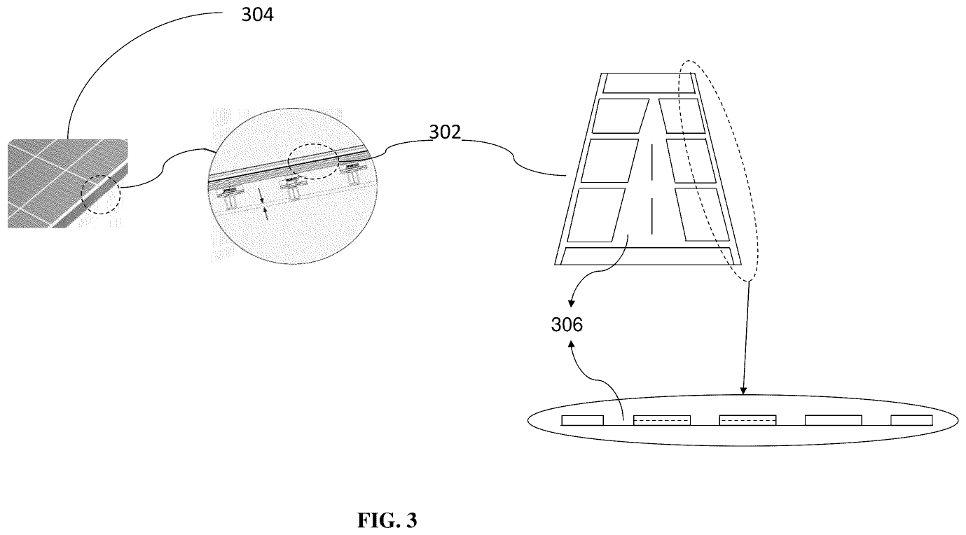

FIG. 3 illustrates a sectional view of a building with an integrated PV design including PV tiles 304 on the roof for an NZEB, further showing an enlarged section of an example tile 302 on which one or more PV elements may be placed, according to some embodiments. Further, while operating, a space for air circulation (air circulation space 306) may be left in between any two PV elements in order to avoid overheating of the PV elements. Further, in some embodiments, selection of the air circulation space 306 may be based on multiple factors. Some of the factors may include, but are not limited to, speed of the wind impinging on the building (in and around the PV elements) and an amount of sunlight impinging on the building (in and around the PV elements). FIG. 3 will be explained in conjunction with the descriptions of FIGS. 1 and 2. In some embodiments, the total power that may be generated by integrated PV tiles 304 on a roof (of an NZEB) may be 11.5 kW/yr. In such a scenario, each PV tile 304 may generate 400 W/yr, and the dimensions of each PV tile 304 may be 1.18×0.54 m². Further, the required surface area may be oriented along full south and east directions. Furthermore, the total production of electricity (by the PV tiles 304) may be 18,400 kWh/yr. In addition, the total demand of electricity (by the NZEB) may be 13,600 kWh/yr. Thus, in such a scenario, the excess electricity obtained from the NZEB may be 4,800 kWh/yr, which may generate a revenue of $200-300/yr. In some embodiments, the one or more PV elements have specific cooling channels helping air circulation and improving the efficiency at the outputs of the PV elements.

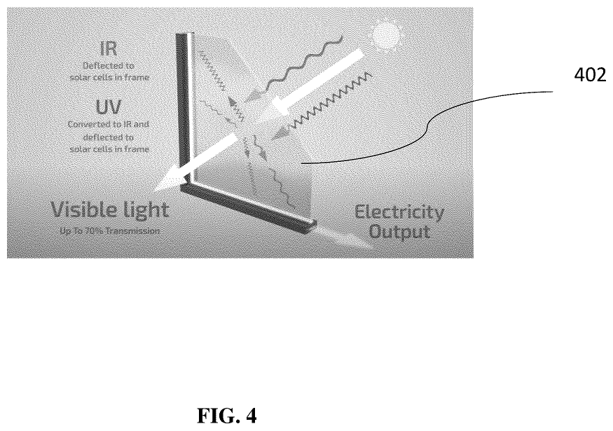

FIG. 4 illustrates an example OPV window 402 for the NZEB, according to some embodiments. FIG. 4 will be explained in conjunction with the descriptions of FIGS. 1-3. FIG. 4 specifically shows an OPV window 402 that may be used to generate electricity for the NZEB. In some embodiments, the OPV window 402 may generate electricity of 3 kW/yr. Further, the OPV window 402 may be integrated into a wall of the NZEB such that the required surface area of the OPV window 402 may be along full south and east directions. Further, in some embodiments, the total electricity produced may be 4,000 kWh/yr.

In some embodiments, solar panels (related to the PV tiles and OPV windows) may absorb energy from the sun's rays and deliver voltage and current to the NZEB. Each panel may produce relatively constant voltage but their currents may vary with the intensity of sunlight falling on the PV shingle tiles and the OPV windows. Further, one or more building elements of the NZEB may include an inverter that helps to convert a produced DC power to AC power to charge devices that run on AC power.

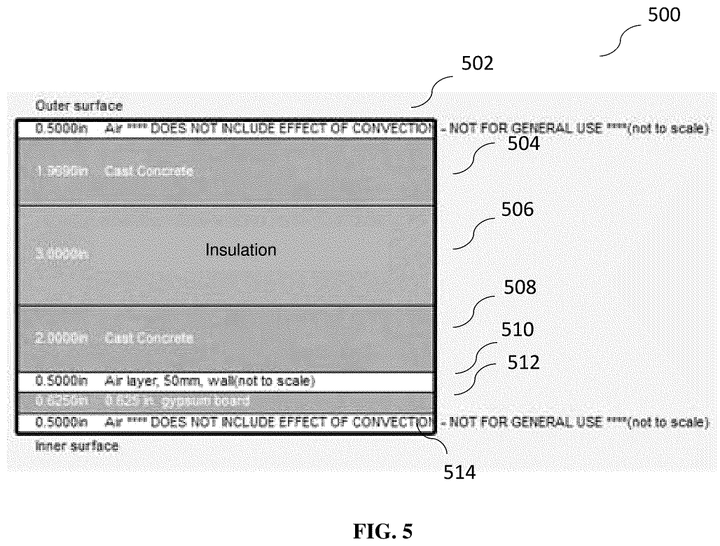

FIG. 5 illustrates the various layers including their associated materials of an example wall 500 for an NZEB, according to some embodiments. FIG. 5 will be explained in conjunction with the description of FIGS. 1-4. FIG. 5 illustrates the arrangement of various layers of the wall 500 which arrangement facilitates external wall insulation. In some embodiments, the external wall may correspond to specific design sandwich panels produced in a fully automated production line. These panels are designed to reduce the amount of energy waste in the NZEB while increasing the durability and sustainability of the NZEB. Further, the usage of pre-cast technology may lead to an increase in the thermal mass of the walls. In some embodiments, the order in which the layers are arranged from external to inside is: Air 502-Pre-cast concrete 504-XPS/polystyrene replaced with hemp wool layer 506-Pre-cast concrete 508-Air 510-Gypsum board 512-Air 514. Those skilled in the art will recognize that the described order is non-limiting and any other order that facilitates external wall insulation may be possible.

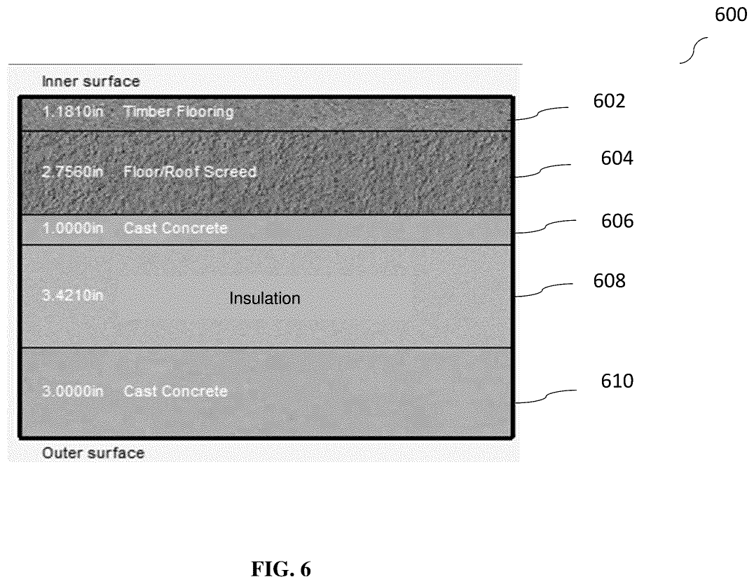

FIG. 6 illustrates the various layers including their associated materials of an example slab floor 600 for an NZEB, according to some embodiments. FIG. 6 will be explained in conjunction with the description of FIGS. 1-5. FIG. 6 illustrates the arrangement of various layers of the slab floor 600 of an NZEB which arrangement facilitates slab floor insulation. In some embodiments, the slab floor 600 may be made up of expanded polystyrene (EPS) that helps in achieving one or more objectives of the NZEB. The order in which the layers are arranged from external to inside is: Timber flooring 602-Floor/roof screed 604-Pre-cast concrete 606-Urea formaldehyde foam layer 608-Pre-cast concrete layer 610. Those skilled in the art will recognize that the described order is non-limiting and any other order that facilitates slab floor insulation may be possible.

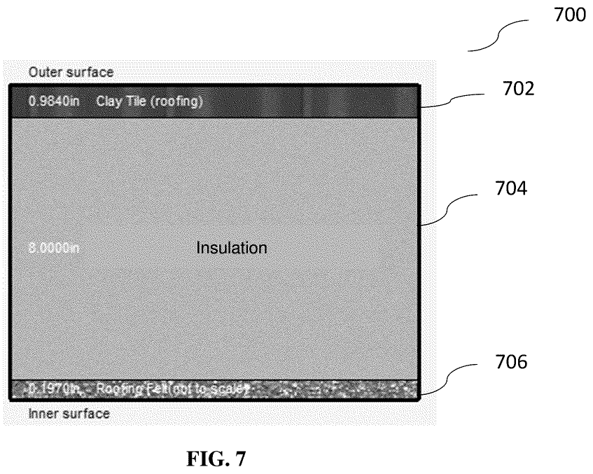

FIG. 7 illustrates the various layers including their associated materials of an example roof 700 for an NZEB, according to some embodiments. FIG. 7 will be explained in conjunction with the descriptions of FIGS. 1-6. FIG. 7 illustrates the arrangement of various layers of the roof 700 of an NZEB which arrangement facilitates roof insulation. In some embodiments, the roof may be designed to minimize the energy loss from the roof. Minimizing the energy loss from the roof may result in a significant reduction (e.g., 25-30% reduction) of energy consumption of the NZEB. Further, interior warm moisture may cause problems (e.g., energy loss) at the roof line when the moisture hits an uninsulated surface, creating a potential for mold issues and reducing the lifetime of the NZEB. Therefore, roof insulation helps to avoid these potential issues. The order in which the layers are arranged from external to inside is: Clay tile 702-MW stone wool layer (rolls) 704-Roofing felt layer 706. Those skilled in the art will recognize that the described order is non-limiting and any other order that facilitates roof insulation may be possible.

With reference to the building blocks disclosed in FIGS. 1-7, in some embodiments various joining methodologies and/or technologies are utilized to join sub-modules/sub-units of individual building blocks or to join one building block with another. For example, some joining technologies are used to build modular building blocks that, when assembled, make a building envelope/enclosure structurally and environmentally seamless. In another example, interconnection methodologies are used between components such as foundation and wall; wall-to-wall and floor level slabs; wall and roof trusses; and roof trusses. In yet another example, interconnection methodologies are used that speed up assembly processes and reduce the need for skilled labor. In yet another example, interconnection technologies are used that allow a high degree of module completion in the factory. In yet another example, digitization of modular building blocks enables repeatability with higher quality levels than traditional methodologies. Further, in some embodiments, an envelope (including modular building blocks) is built to have an energy-efficient thermal shell and appliances, and renewable energy systems; and to provide thermal comforts of the residents (inside the envelope).

The terms “comprising,” “including,” and “having,” as used in the specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition, or step being referred to is an optional (not required) feature of the invention. The term “connecting” includes connecting, either directly or indirectly, and “coupling,” including through intermediate elements.

The invention has been described with reference to various specific and preferred embodiments and techniques. However, it should be understood that many variations and modifications may be made while remaining within the spirit and scope of the invention. It will be apparent to one of ordinary skill in the art that methods, devices, device elements, materials, procedures, and techniques other than those specifically described herein can be applied to the practice of the invention as broadly disclosed herein without resorting to undue experimentation. All art-known functional equivalents of methods, devices, device elements, materials, procedures, and techniques described herein are intended to be encompassed by this invention. Whenever a range is disclosed, all subranges and individual values are intended to be encompassed. This invention is not to be limited by the embodiments disclosed, including any shown in the drawings or exemplified in the specification, which are given by way of example and not of limitation. Additionally, it should be understood that the various embodiments of the building blocks described herein contain optional features that can be individually or together applied to any other embodiment shown or contemplated here to be mixed and matched with the features of that building block.

While the disclosure has been described with respect to a limited number of embodiments, those skilled in the art, having benefit of this disclosure, will appreciate that other embodiments can be devised which do not depart from the spirit and scope of the disclosure as disclosed herein.

We claim:

1. A method of designing and constructing a net-zero energy building (NZEB), the method comprising:
generating a design model for the NZEB based at least in part on one or more requirements of a user, wherein the design model is for estimating energy consumption for the NZEB over a predetermined period of time, wherein the NZEB comprises one or more building elements and one or more air-ventilation elements, and wherein at least one of the one or more building elements comprises pre-cast concrete; and
selecting at least one characteristic for one or more building parameters of the one or more building elements such that the estimated energy consumption for the NZEB is within a predetermined range,
wherein the one or more air-ventilation elements comprise at least one heat pump with a programmable thermostat for heating, ventilation, and air conditioning (HVAC), and the one or more building elements comprise one or more photovoltaic (PV) tiles and one or more organic PV (OPV) windows.

2. The method of claim 1, further comprising, in the design model, varying airtightness and indoor environment quality of the NZEB, wherein varying the airtightness and the indoor environment quality of the NZEB comprises:
sealing the one or more OPV windows, penetrations, and openings in the one or more building elements of the NZEB; and
controlling a ventilation airflow design rate and run-time, and an infiltration rate in the NZEB.

3. The method of claim 1, wherein the one or more building elements comprise walls including a plurality of materials, and wherein the method further comprises:
arranging, in the design model, the plurality of materials in layers to improve an insulation of the walls.

4. The method of claim 3, wherein the insulation of the walls is modeled in a range of R-13 to R-20.

5. The method of claim 3, further comprising modeling insulation of the walls to include hemp wool.

6. The method of claim 1, wherein the one or more building elements comprise slab floors including a plurality of materials, and wherein the method further comprises:
arranging, in the design model, the plurality of materials in layers to improve an insulation of the slab floors.

7. The method of claim 6, wherein the insulation of the slab floors is modeled in a range of R-13 to R-17.

8. The method of claim 1, wherein the one or more building elements comprise a ceiling including a plurality of materials, and wherein the method further comprises:
arranging, in the design model, the plurality of materials in layers to improve an insulation of the ceiling.

9. The method of claim 8, wherein the insulation of the ceiling is modeled at approximately R-30.

10. The method of claim 1, wherein the one or more OPV windows are modeled to a U-value of 0.65 or less, and a solar heat gain co-efficient (SHGC) value of 0.26 or less.

11. The method of claim 1, further comprising modeling the programmable thermostat based at least in part on the one or more requirements of the user.

12. The method of claim 1, wherein the one or more building elements comprise ducts and air handlers in a conditioned space of the NZEB.

13. The method of claim 1, further comprising modeling the at least one heat pump to include a runtime, positive pressure, filtered fresh air ventilation system used for the HVAC.

14. The method of claim 1, further comprising using the one or more building elements and the one or more air-ventilation elements to build the NZEB, wherein using the one or more building elements and the one or more air-ventilation elements to build the NZEB comprises constructing the NZEB based at least in part on the user requirements and the selected at least one characteristic for the one or more building parameters.

15. The method of claim 1, wherein the estimated energy consumption is zero or less.

16. A system for designing and constructing a net-zero energy building (NZEB), the system comprising:
a design module operable to generate a design model for the NZEB based at least in part on one or more requirements of a user, wherein the design model is for estimating energy consumption for the NZEB over a predetermined period of time, wherein the NZEB comprises one or more building elements and one or more air-ventilation elements, and wherein at least one of the one or more building elements comprises pre-cast concrete; and
a selection module operable to select at least one characteristic for the one or more building parameters of the one or more building elements such that the estimated energy consumption for the NZEB is within a predetermined range;
wherein the one or more air-ventilation elements comprise at least one heat pump with a programmable thermostat for heating, ventilation, and air conditioning (HVAC), and the one or more building elements comprise one or more photovoltaic (PV) tiles and one or more organic PV (OPV) windows.

17. The system of claim 16, wherein the design module is further operable to:
model sealing of the one or more OPV windows, penetrations, and openings in the one or more building elements of the NZEB; and
model controlling of a ventilation airflow design rate and run-time, and an infiltration rate in the NZEB.

18. The system of claim 16, wherein the one or more building elements comprise walls including a plurality of materials, and wherein the design module is further operable to:
model arranging of the plurality of materials in layers to improve an insulation of the walls, and
wherein the insulation of the walls is modeled in a range of R-13 to R-20.

19. The system of claim 16, wherein the one or more building elements comprise slab floors including a plurality of materials, and wherein the design module is further operable to:
model arranging of the plurality of materials in layers to improve an insulation of the slab floors, and
wherein the insulation of the slab floors is modeled in a range of R-13 to R-17.

20. The system of claim 16, wherein the one or more building elements comprise a ceiling including a plurality of materials, and wherein the design module is further operable to:
model arranging of the plurality of materials in layers to improve an insulation of the ceiling, and
wherein the insulation of the ceiling is modeled at approximately R-30.

21. The system of claim 16, wherein the one or more OPV windows are modeled to a U-value of 0.65 or less, and a solar heat gain co-efficient (SHGC) of 0.26 or less.

22. The system of claim 16, wherein the design module is further operable to model the programmable thermostat based at least in part on the one or more requirements of the user.

23. The system of claim 16, wherein the design module is further operable to determine, prior to selection of the at least one characteristic for the one or more building parameters, the one or more building parameters such that the estimated energy consumption of the NZEB over the predetermined period of time is within the predetermined range, wherein the system further comprises an element building module operable to use the one or more building elements and the one or more air-ventilation elements to build the NZEB.

24. A system for designing and constructing a net-zero energy building (NZEB), the system comprising:
a processor; and
a memory comprising computer-executable instructions that when executed by the processor perform the steps:
generating a design model for the NZEB based at least in part on one or more requirements of a user, wherein the design model is for estimating energy consumption for the NZEB over a predetermined period of time, wherein the NZEB comprises one or more building elements and one or more air-ventilation elements, and wherein at least one of the one or more building elements comprises pre-cast concrete; and
selecting at least one characteristic for the one or more building parameters of the one or more building elements such that the estimated energy consumption for the NZEB is within a predetermined range;
wherein the one or more air-ventilation elements comprise at least one heat pump with a programmable thermostat for heating, ventilation, and air conditioning (HVAC), and the one or more building elements comprise one or more photovoltaic (PV) tiles and one or more organic PV (OPV) windows.
